(19) United States
(12) Patent Application Publication
(10) Pub. No.: US 2011/0065051 A1
(43) Pub. Date: Mar. 17, 2011

(54) SUPPORTING DEVICE, OPTICAL APPARATUS, EXPOSURE APPARATUS, AND DEVICE MANUFACTURING METHOD

(75) Inventor: Yuji Sudoh, Hadano-shi (JP)

(73) Assignee: CANON KABUSHIKI KAISHA, Tokyo (JP)

(21) Appl. No.: 12/876,940

(22) Filed: Sep. 7, 2010

(30) Foreign Application Priority Data
Sep. 11, 2009 (JP) 2009-210281

(51) Int. Cl. G03F 7/20; G02B 7/02

(52) U.S. Cl. 430/325; 359/811

(57) ABSTRACT

A supporting device that supports an optical element in a gravitational force direction, the supporting device comprises: a supporting member to be connected via an adhesive to an outer circumference of the optical element, the supporting member including a plurality of members each of which has a projection for supporting the optical element. Each of the plurality of members is arranged to have a rigidity lower than that of the adhesive in a direction orthogonal to the gravitational force direction.

### BACKGROUND OF THE INVENTION

1. Field of the Invention

The present invention relates to a supporting device, an optical apparatus, an exposure apparatus, and a device manufacturing method.

2. Description of the Related Art

An exposure apparatus exemplified by a semiconductor exposure apparatus is an apparatus that transfers a pattern formed on an original plate (e.g., reticle) onto a substrate (e.g., silicon wafer). During pattern transfer, a projection optical system is employed for imaging the pattern on the reticle onto a wafer. In order to produce a highly integrated circuit, a high resolution power is required for the projection optical system. It is necessary to minimize the aberration of the projection optical system for a semiconductor exposure apparatus. Hence, the positioning of the optical elements constituting the projection optical system needs to be performed with a very high accuracy. It is also required that the optical element positioned with a desired accuracy is not inadvertently displaced due to an external force such as vibration/shock during assembling and transportation, environmental temperature change, and the like (e.g., see Japanese Patent Laid-Open No. 2001-343576).

For the lens barrel structure such as that for a projection optical system, the shape, attitude, and position of a lens (optical element) or a lens barrel component are independently changed in association with environmental temperature change, which may result in a change in the aberration. In particular, glass material such as quartz or fluorite is employed for an exposure apparatus in which a short wavelength light source is used. Since such a material that is used and a lens barrel component have different coefficients of thermal expansion, a uniform expansion or a uniform contraction may not be achieved. Consequently, the lens surface shape changes, and thus the influence of a variation caused by temperature on the aberration cannot be ignored.

In order to reduce the aberration change, an adhesive having the elasticity of a hard rubber may be filled between a lens and a metal frame. With this arrangement, the relative displacement between the lens and the metal frame due to environmental temperature change is absorbed to thereby support the lens. In this structure, the frictional force f, which is determined by the weight and friction coefficient of the lens, occurs at the supporting point, which is formed along the inner circumference of the metal frame, for supporting the lens in the gravitational force direction. An external force equal to or greater than the frictional force f may be applied to the lens due to environmental temperature change or vibration/shock during manufacturing or transportation, resulting in the occurrence of a positional shift of the lens with respect to the metal frame. In this case, although the lens should be restored to its original position due to the elastic force of the adhesive, the lens may not be restored to its original position depending on the magnitude of the frictional force f. This may lead to a decrease in performance of the optical system.

### SUMMARY OF THE INVENTION

The present invention provides, for example, a supporting device that has an advantage in the positional stability of the optical element.

In view of the foregoing, according to an aspect of the present invention, a supporting device that supports an optical element in a gravitational force direction, the supporting device comprises: a supporting member to be connected via an adhesive to an outer circumference of the optical element, the supporting member including a plurality of members each of which has a projection for supporting the optical element, wherein each of the plurality of members is arranged to have a rigidity lower than that of the adhesive in a direction orthogonal to the gravitational force direction.

According to the present invention, for example, a supporting device that has an advantage in the positional stability of the optical element may be provided.

Further features of the present invention will become apparent from the following description of exemplary embodiments with reference to the attached drawings.

### BRIEF DESCRIPTION OF THE DRAWINGS

FIG. 1 is a perspective view illustrating a supporting device according to a first embodiment of the present invention.

FIG. 2 is an enlarged perspective view illustrating an elastic supporting member 3 according to the first embodiment of the present invention.

FIG. 3 is an enlarged perspective view illustrating another example of the elastic supporting member 3.

FIG. 4 is a perspective view illustrating a supporting device according to a second embodiment of the present invention.

FIG. 5 is an enlarged perspective view illustrating a lens supporting unit 5 shown in FIG. 4.

FIG. 6 is a view schematically illustrating a semiconductor exposure apparatus to which a supporting device according to an embodiment of the present invention is applied.

### DESCRIPTION OF THE EMBODIMENTS

Hereinafter, preferred embodiments of the present invention will now be described with reference to the accompanying drawings. While the following description will be made using specific numeric values, configurations, operations, and the like, these may be appropriately changed according to the specifications.

### First Embodiment

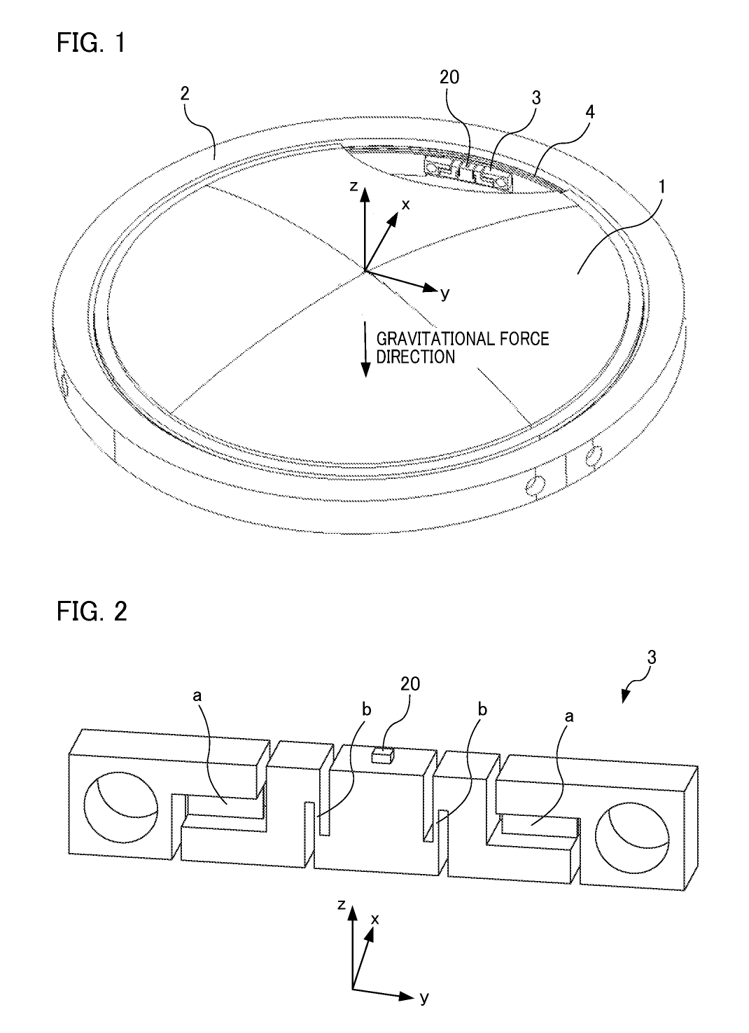

FIG. 1 is a perspective view illustrating a supporting device according to a first embodiment of the present invention. For the convenience of explanation, a part of a lens 1 is cut out. The x, y, and z axes shown in FIG. 1 represent the three-dimensional orthogonal coordinate axes. The gravitational force direction is coincident with the optical axis of the lens 1, and is the −z direction.

The supporting device of the present embodiment includes a lens 1, a supporting member 2, a plurality of members (hereinafter referred to as “elastic supporting member”) 3, and an adhesive 4. As shown in FIG. 1, the supporting member 2 is connected via the adhesive 4 to the outer circumference of the lens 1 to thereby support the lens 1. In order to coaxially support the lens 1, the supporting member 2 is supported by a lens barrel (not shown). Three inner circumferential portions of the supporting member 2 are cut out. The elastic supporting member 3, including a plurality of leaf springs (plate-like springs) is provided for each of three portions. The three elastic supporting members 3 are provided at an angle interval of 120 degree around the z axis. The both ends of the elastic supporting member 3 are connected to the supporting member 2 via fastening members such as bolts or the like, and a projection 20, which supports the lens 1 in the gravitational force direction, is formed at the central portion of the elastic supporting member 3. The lens 1 is supported by the projection 20 of the elastic supporting member 3 in the gravitational force direction. The lens 1 is connected to the entire circumference of the inner circumferential portion of the supporting member 2 both in the gravitational force direction and the vertical direction with the aid of the adhesive 4 that is filled in a space between the peripheral region of the lens 1 and the inner circumference of the supporting member 2. The adhesive 4 consists of a material having an elasticity approximately equal to that of hard rubber so as to absorb lens deformation caused by an external force. In the present embodiment, the adhesive 4 of which the Young's modulus is adjusted in the range of 1 to 10 MPa is employed. Also, the lens 1 of the present embodiment consists of quartz.

FIG. 2 is an enlarged perspective view illustrating the elastic supporting member 3 of the present embodiment. The elastic supporting member 3 is arranged to have a lower rigidity than that of the adhesive 4 in a direction orthogonal (perpendicular) to the gravitational force direction. As shown in FIG. 2, the elastic supporting member 3 is provided with two springs a having a low rigidity in the x-axis direction and two springs b having a low rigidity in the y-axis direction. With these two pairs of the springs, the projection 20 provided at the center of the elastic supporting member 3 is readily displaceable in all directions within the xy-plane, including the two axes orthogonal (perpendicular) to the gravitational force direction. In the present embodiment, the spring constant in a direction within the xy-plane of the elastic supporting member 3 is designed to be less than or equal to ⅕ of the spring constant of the adhesive 4. Each of the springs a and b in the plate-spring shape has rigidity higher than that in a direction within the xy-plane in the z-axis direction shown in FIG. 2, and is designed such that a settling of the lens 1 falls less than or equal to the desired amount when the weight of the lens 1 is applied to the projection 20. Note that the elastic supporting member 3 is designed to have rigidity higher than that of the adhesive 4 in the z-axis direction. According to the present embodiment, even when an external force is temporarily applied to the lens 1 due to temperature change, vibration/shock, and the like, and the lens 1 is thereby relatively displaced with respect to the projection 20 in the x- and y-axis direction, the lens 1 can be readily restored to its original position. In other words, since the projection 20 is displaceable while having low rigidity within the xy-plane, a force that prevents the effects of the restoration of the lens 1 back to its original position due to the elasticity of the adhesive 4 is small. According to this configuration, the positional reproducibility, which is less than or equal to ⅕ of a relative displacement amount, can be ensured.

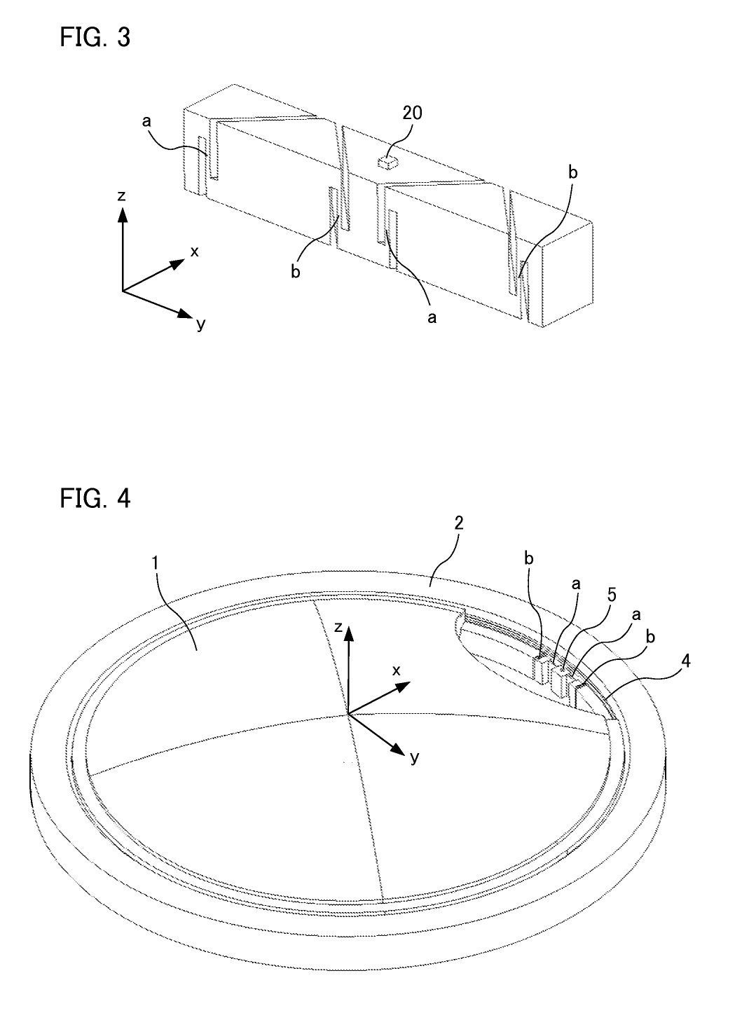

FIG. 3 is an enlarged perspective view illustrating another example of the elastic supporting member 3. In this example shown in FIG. 3, the spring arrangement of the elastic supporting member 3 shown in FIG. 2 has been changed. More specifically, in the occupied space equivalent to that shown in FIG. 2, the rigidity in the z-axis direction is maintained while reducing the rigidity within the xy-plane. The springs of the elastic supporting member 3 are configured to have an angle with respect to the x and y axes such that the widthwise dimension of the springs is increased (the spring a and b are disposed in a shape of inverse “V” when viewed from the z-axis direction). With this arrangement, the degree of freedom in design of the springs can be increased. This enables obtaining the positional reproducibility with a high accuracy when the positional shift of a lens temporarily occurs.

### Second Embodiment

FIG. 4 is a perspective view illustrating a supporting device according to a second embodiment of the present invention. In FIG. 4, components similar to those in the first embodiment are designated by the same reference numerals, and therefore, the explanation regarding the aforesaid components and coordinate setting will not be given here. In the second embodiment, the lens supporting unit 5 for supporting the lens 1 is formed at the supporting member 2.

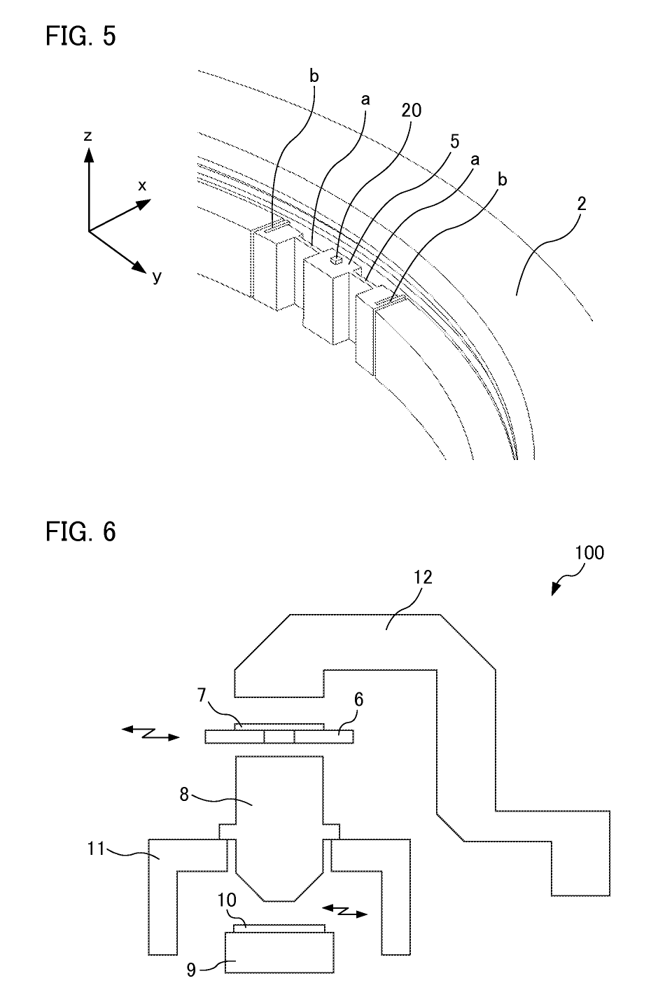

FIG. 5 is an enlarged perspective view illustrating the lens supporting unit 5 shown in FIG. 4. Compared to the rigidity of the adhesive 4, the spring a has low rigidity in the x-axis direction, and the spring b has low rigidity in the y-axis direction. The three lens supporting units 5 are provided along the inner circumferential portion of the supporting member 2 at an angle interval of 120 degree around the optical axis. The lens supporting units 5 are formed integrally with the supporting member 2 by means of wire electrical discharge machining. While in the first embodiment, the elastic supporting member 3 and the supporting member 2 are two separate members and are fastened by bolts, in the second embodiment, the lens supporting units 5 are processed and formed at the supporting member 2. This arrangement reduces the potential for the occurrence of the relative positional shift at the points where the elastic supporting member 3 is fastened to the supporting member 2 in association with environmental temperature variations and vibration/shock. Consequently, positional stability of the lens 1 is improved.

FIG. 6 is a view schematically illustrating an exposure apparatus to which the supporting device according to the aforementioned embodiment is applied. The exposure apparatus 100 includes a reticle stage 6, a reticle 7, a projection optical system 8, a wafer stage 9, and a frame 11. The reticle stage 6 moves in the left and right directions shown by the arrow in FIG. 6 with the reticle 7 mounted. A wafer 10 is mounted on the wafer stage 9. Illumination light for exposure is irradiated from the illumination optical system 12 to a part of the reticle 7 mounted on the reticle stage 6. An illumination light source is, for example, an excimer laser having a wavelength of 193 nm (nanometer). The irradiation area is a slit-like irradiation area which partially covers the pattern area of the reticle 7. The pattern corresponding to the slit section is reduced, for example, in size to ¼ of the original plate and is projected on the wafer 10 mounted on the wafer stage 9 by the projection optical system 8. The projection optical system 8 is mounted on the frame 11 of the exposure apparatus. The reticle 7 and the wafer 10 are scanned relative to the projection optical system 8 to thereby transfer the pattern area of the reticle 7 onto a photoresist coated on the wafer 10. The scanning exposure is repeatedly performed relative to a plurality of transfer areas (shot) on the wafer 10. The projection optical system 8 requires a high level of resolution performance, and the structure for supporting the optical element requires high accuracy. Hence, the aforementioned supporting device may be employed for supporting the optical elements such as lenses or the like, which configure the projection optical system 8. Note that the aforementioned supporting device may be employed for supporting the optical elements configuring another optical system such as the illumination optical system 12 or the like.

While in the embodiment, the supporting device is applied only to a lens of which the optical performance is significantly influenced by its positional shift, the supporting device may also be applied to the support of a plurality of or all of the lenses. Thereby, even when an external force such as vibration/shock is momentarily applied to the lens during manufacturing or transportation and due to occurrence such as electrical failure or earthquake, environmental temperature change, or the like, or even when the positional shift of the lens momentarily occurs within the lens barrel, the lens can be restored to its original position at a high accuracy. Consequently, the lens can be supported with a high stability, whereby a lens system can be realized for obtaining the resolution power required for semiconductor manufacturing.

### (Application to Other Systems)

While a description has been made of an example in which the present invention is applied to the support of a lens provided in the projection optical system of the exposure apparatus, a reflection element such as a mirror may be used as an optical element. A diffraction element may also be used. The present invention may be applied to an optical element for which a high positioning stability is required.

### (Device Manufacturing Method)

Next, a method of manufacturing a device (semiconductor device, liquid crystal display device, and the like) as an embodiment of the present invention is described. The semiconductor device is manufactured through a front-end process in which an integrated circuit is formed on a wafer, and a back-end process in which an integrated circuit chip is completed as a product from the integrated circuit on the wafer formed in the front-end process. The front-end process includes a step of exposing a wafer coated with a photoresist to light using the above-described exposure apparatus of the present invention, and a step of developing the exposed wafer. The back-end process includes an assembly step (dicing and bonding), and a packaging step (sealing). The liquid crystal display device is manufactured through a process in which a transparent electrode is formed. The process of forming a plurality of transparent electrodes includes a step of coating a glass substrate with a transparent conductive film deposited thereon with a photoresist, a step of exposing the glass substrate coated with the photoresist to illuminate using the above-described exposure apparatus, and a step of developing the exposed glass substrate. The device manufacturing method of this embodiment has an advantage, as compared with a conventional device manufacturing method, in at least one of performance, quality, productivity and production cost of a device.

The present invention is applicable to the support of an optical element provided in an optical apparatus, such as an exposure apparatus, which is employed in the semiconductor manufacturing process.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-210281 filed on Sep. 11, 2009 which is hereby incorporated by reference herein in its entirety.

What is claimed is:

1. A supporting device that supports an optical element in a gravitational force direction, the supporting device comprising:
a supporting member to be connected via an adhesive to an outer circumference of the optical element, the supporting member including a plurality of members each of which has a projection for supporting the optical element,
wherein each of the plurality of members is arranged to have a rigidity lower than that of the adhesive in a direction orthogonal to the gravitational force direction.

2. The supporting device according to claim 1, wherein each of the plurality of members is arranged to have a rigidity lower than that of the adhesive in two directions that are orthogonal to the gravitational force direction and that are orthogonal to each other.

3. The supporting device according to claim 1, wherein each of the plurality of members is arranged to have a rigidity higher than that of the adhesive in the gravitational force direction.

4. The supporting device according to claim 1, wherein each of the plurality of members includes a leaf spring.

5. An optical apparatus comprising:
an optical element; and
a supporting device defined in claim 1 that supports the optical element.

6. An exposure apparatus that comprises an optical system and exposes a substrate to a light via the optical system,
wherein the optical system includes a supporting device defined in claim 1 that supports an optical element included in the optical system.

7. A method of manufacturing a device, the method comprising the steps of:
exposing a substrate to a light using an exposure apparatus defined in claim 6;
developing the exposed substrate; and
processing the developed substrate to manufacture the device.
